(19) United States
(12) Patent Application Publication
(10) Pub. No.: US 2011/0019358 A1
(43) Pub. Date: Jan. 27, 2011

(54) ALL-IN-ONE COMPUTER

(75) Inventors: YI-LAN LIAO, Tu-Cheng (TW); TSUNG-HSI LI, Tu-Cheng (TW); SHU-YUN HUANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/637,636

(22) Filed: Dec. 14, 2009

(30) Foreign Application Priority Data
Jul. 27, 2009 (CN) 200910304864.1

(51) Int. Cl. G06F 1/20; H05K 7/20

(52) U.S. Cl. 361/679.46

(57) ABSTRACT

An all-in-one computer includes a front enclosure and a rear enclosure fixed together. The front enclosure includes a rear piece opposite to the front enclosure, and two side pieces extending forwards from left and right ends, respectively. The rear piece defines an air outlet including a number of first holes each having a width or diameter between 1 mm and 2 mm. Each side piece defines an air intake including a number of vertically spaced elongated second holes. The front enclosure and the rear enclosure cooperatively bound an airtight space except communicating with outside via the air intakes and the air outlet. Each second hole is slanted lengthwise down towards the front enclosure with a first slanting angle of not less than 15 degrees. A bottom wall of each second hole is slanted down outwards with a second slanting angle of not less than 30 degrees.

### BACKGROUND

1. Technical Field

The present disclosure relates to all-in-one computers, and more particularly to an all-in-one computer with splash protection capability.

2. Description of Related Art

A point of sale (POS) computer is an example of an all-in-one computer in the service industry. POS computers are commonly used in restaurants and so are at risk of having food and beverage spilled on them. Therefore, splash protection is required for the POS computer to be used in such environments. Unfortunately, venting of the computer is needed to dissipate heat and makes it difficult to keep liquid from getting into the computer.

### BRIEF DESCRIPTION OF THE DRAWINGS

FIG. 1 is an isometric view of an embodiment of an all-in-one computer, the all-in-one computer including a rear enclosure.

FIG. 2 is an isometric view of the rear cover in FIG. 1, but viewed from another perspective.

FIG. 3 is a front plan view of the rear enclosure in FIG. 2.

FIG. 3 is a side plan view of the rear enclosure in FIG. 2.

### DETAILED DESCRIPTION

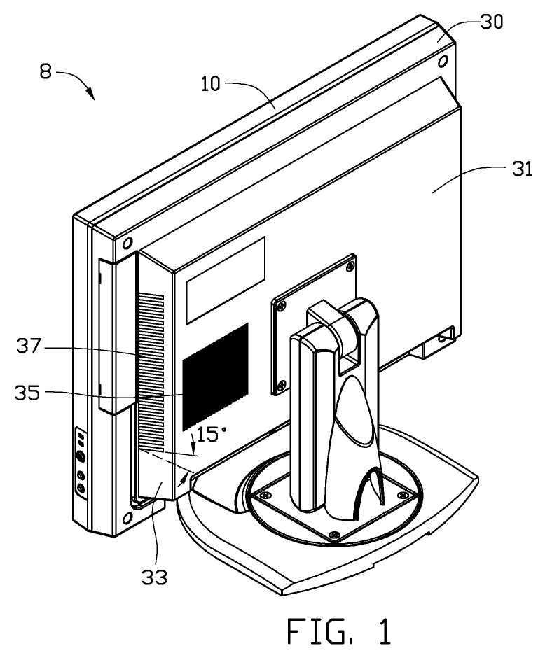

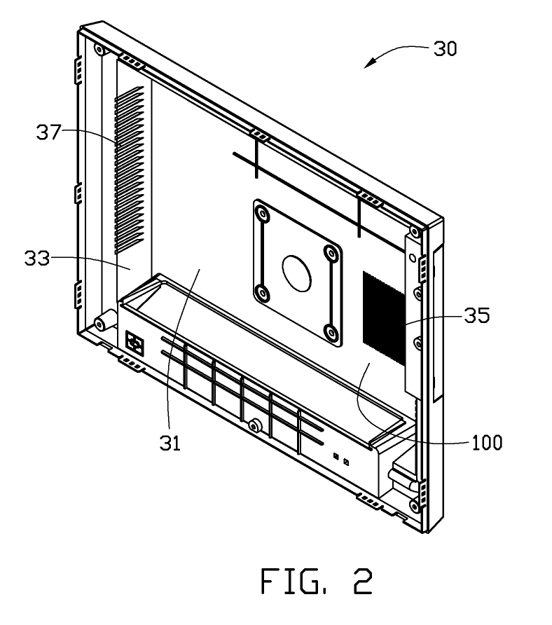

Referring to FIG. 1, an embodiment of an all-in-one computer 8 includes a front enclosure 10 and a rear enclosure 30 fixed together and cooperatively bounding a space 100 (see FIG. 2) for receiving electronic elements of the computer 8. The computer 8 is provided with vents of a size and configuration that reduce or even eliminate the possibility of liquid or food particles spilled on or around the computer 8 to penetrate the computer 8.

The front enclosure 10 includes a rectangular frame (not labeled) defining an opening (not shown), and a liquid crystal panel (not shown) mounted to the frame covering the opening.

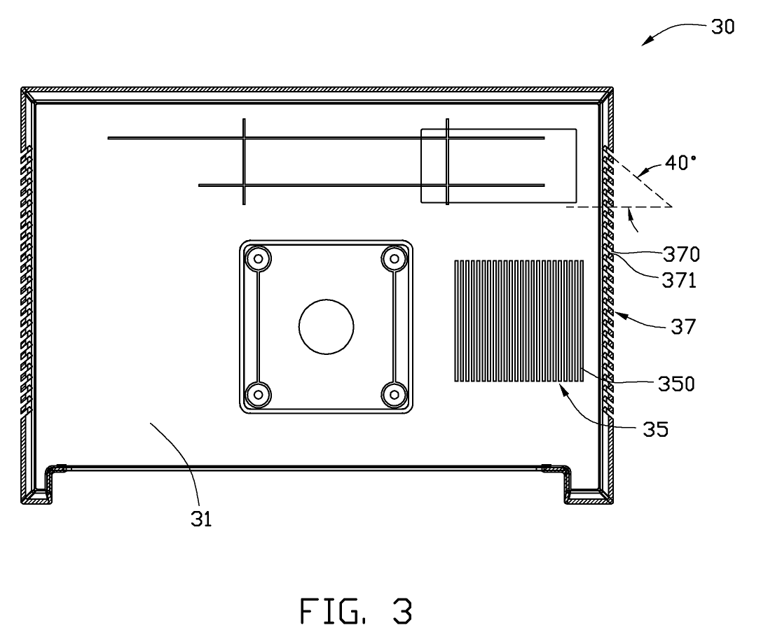

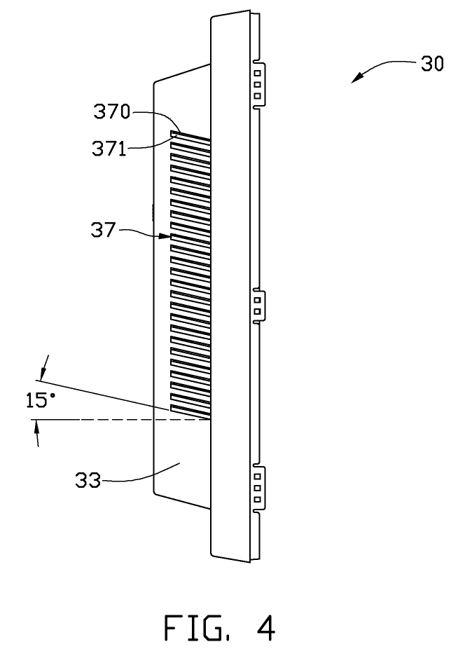

Referring to FIGS. 2-4, the rear enclosure 30 includes a rectangular rear piece 31, and two side pieces 33 extending from left and right ends of the rear piece 31, respectively. The rear piece 31 defines an air outlet 35. A fan (not shown) is received in the computer 8, facing the air outlet 35. The air outlet 35 includes a plurality of horizontally spaced vertical slots 350 defined in the rear piece 31. A width of each of the plurality of slots 350 is about 1.5 millimeters (mm). Each side piece 33 defines an air intake 37. Air is driven to flow into the computer 8 through the air intakes 37 by the fan, and is exhausted through the air outlet 35 to dissipate heat. Each air intake 37 includes a plurality of vertically spaced elongated holes 370 defined in the corresponding side piece 33. Each hole 370 is slanted lengthwise down towards the front enclosure 10. In the present embodiment, an angle between the lengthwise axis of each hole 370 and the horizontal line is substantially 15 degrees. A bottom wall 371 bounding each hole 370 is slanted down and outwards. In the present embodiment, an angle between the bottom wall 371 bounding each hole 370 and a thickness direction of the corresponding side piece 33 is substantially 40 degrees.

It is noted that the computer 8 is airtight except for through the air intakes 37 and the air outlet 35.

The computer 8 may be used in a restaurant or the like, where beverages may be splashed or spilled on or around the computer 8 by accident. In practice, because the front enclosure 10 usually faces a user, it has the greatest chance of getting wet, the top and the left and right sides of the computer 8 has less chance, and the back of the computer 8 has little chance to be splashed or spilled on.

Seams where various components, such as the liquid crystal panel and the frame of the front enclosure 10, of the computer 8 meet are sealed according to known technology and so are considered water-proof in this embodiment and not described in detail.

If the liquid is splashed to the top of the computer 8, the liquid will flow down along the rear piece 31 and the side pieces 33 of the rear enclosure 30. When the liquid flows to the air outlet 35 of the rear piece 31, because the width of each slot 350 of the air outlet 35 is small enough, taken 1.5 mm as an example of the width, surface tension of the liquid will postpone the liquid to flow into the computer 8 through the slots 350, until the liquid vaporizes. In addition, heated air is blown to outside the computer 8 through the slots 350 of the air outlet 35, which provides additional airflow and heat to vaporize liquids, and therefore it is even more difficult for the liquid to flow into the computer 8 through the slots 350. When the liquid flows to the air intakes 37 of the side pieces 33, because the bottom wall 371 bounding each hole 370 is slanted down outwards for a big enough angle, taken 40 degrees as an example of the angle, the liquid will be guided to flow outside the holes 370, avoiding flowing inwards, and because each hole 370 is slanted down towards the front enclosure 10, the liquid will be guided along each hole 370 to flow towards the front enclosure 10 and meet together to fast flow down to leave the computer 8.

Furthermore, in practice, people are conditioned to lean back the display for not more than 15 degrees when using a computer. Therefore, in order to avoid the liquid flow from the air intakes 37 to the rear piece 31 to increase burden of splash protection for the air outlet 33, each hole 370 of the air intakes 37 should be slanted down towards the front enclosure 10 for a big enough angle for the avoidance, in other words, the angle should be at least for 15 degrees.

If the liquid is splashed to the left or right side of the computer 8, the situation is similar to that the liquid is splashed to the top of the computer 8, so repeat no more here.

The computer 8 of the present disclosure has passed the test of IPX2, and therefore the computer 8 suits the splash protection requirement in a restaurant or the like environment. It is noted that, the “IP” in “IPX2” points to a standard of splash protection capability, and the “X2” points to one of the splash protection levels of the standard.

In other embodiments, the width of each slot 350 of the air outlet 35 may not be 1.5 mm, and may be another value, e.g., between 1 mm and 2 mm. Furthermore, the slots 350 of the air outlet 35 may be replaced by round holes each having a diameter between 1 mm and 2 mm.

In other embodiments, the slanting angle of the bottom wall 371 bounding each hole 370 of the air intakes 37 may not be 40 degrees, and may be another angle more than 30 degrees which ensures the splash protection capability of the air intakes 37, especially when the liquid is splashed to the left or right side of the computer 8.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An all-in-one computer comprising:
a front enclosure; and
a rear enclosure comprising a rear piece opposite to the front enclosure, and two side pieces extending from left and right ends of the rear piece respectively towards the front enclosure, wherein the rear piece defines an air outlet, the air outlet comprises a plurality of first holes defined in the rear piece, each first hole has a width or diameter between 1 millimeter (mm) and 2 mm, each side piece defines an air intake, each air intake comprises a plurality of vertically spaced elongated second holes defined in the corresponding side piece;
wherein the front enclosure and the rear enclosure are fixed together and cooperatively bound an airtight space except communicating with outside via the air intakes and the air outlet, each second hole is slanted lengthwise down towards the front enclosure with a first slanting angle of not less than 15 degrees, a bottom wall of each second hole is slanted down outwards with a second slanting angle of not less than 30 degrees.

2. The all-in-one computer of claim 1, wherein the first slanting angle is 15 degrees.

3. The all-in-one computer of claim 2, wherein the second slanting angle is 40 degrees.

4. The all-in-one computer of claim 1, wherein each first hole is a vertical slot with a width between 1 mm and 2 mm.

5. The all-in-one computer of claim 4, wherein the width of each first hole is about 1.5 mm.

6. The all-in-one computer of claim 5, wherein the slots of the air outlet are horizontally spaced.

7. An all-in-one computer comprising:
a front enclosure; and
a rear enclosure fixed to the front enclosure and comprising a rear piece opposite to the front enclosure, and a side piece extending from one of the left and right ends of the rear piece towards the front enclosure, wherein the rear piece defines an air outlet, the air outlet comprises a plurality of first holes defined in the rear piece, each first hole has a width or diameter between 1 mm and 2 mm, the side piece defines an air intake, the air intake comprises a plurality of vertically spaced elongated second holes defined in the corresponding side piece, each second hole is slanted lengthwise down towards the front enclosure with a first slanting angle of not less than 15 degrees, a bottom wall bounding each second hole is slanted down outwards with a second slanting angle of not less than 30 degrees.

8. The all-in-one computer of claim 7, wherein the first slanting angle is 15 degrees.

9. The all-in-one computer of claim 7, wherein the second slanting angle is 40 degrees.

10. The all-in-one computer of claim 7, wherein each first hole is a vertical slot with a width between 1 mm and 2 mm.

11. The all-in-one computer of claim 10, wherein the width of each first hole is about 1.5 mm.

12. The all-in-one computer of claim 10, wherein the slots of the air outlet are horizontally spaced.

13. An all-in-one computer comprising:
a rear piece defining an air outlet, wherein the air outlet comprises a plurality of first holes defined in the rear piece, each first hole has a width or diameter between 1 mm and 2 mm; and
a side piece extending forwards from one of left and right ends of the rear piece, wherein the side piece defines an air intake, the air intake comprises a plurality of vertically spaced elongated second holes defined in the side piece, each second hole is slanted lengthwise down forwards with a first slanting angle of not less than 15 degrees, a bottom wall bounding each second hole is slanted down outwards with a second slanting angle of not less than 30 degrees.

14. The all-in-one computer of claim 13, wherein the second slanting angle is 40 degrees.

15. The all-in-one computer of claim 14, wherein the first slanting angle is 15 degrees.

16. The all-in-one computer of claim 13, wherein each first hole is a vertical slot with a width between 1 mm and 2 mm.

17. The all-in-one computer of claim 16, wherein the slots of the air outlet are horizontally spaced.

18. The all-in-one computer of claim 17, wherein the width of each first hole is 1.5 mm.
